(19) United States
(12) Patent Application Publication
(10) Pub. No.: US 2025/0151446 A1
(43) Pub. Date: May 8, 2025

(54) RADIATION DETECTOR, DETECTION UNIT, AND RADIATION IMAGING SYSTEM

(71) Applicant: CANON KABUSHIKI KAISHA, Tokyo (JP)

(72) Inventors: ZEMPEI WADA, Saitama (JP); FUMIAKI MIZUTANI, Kanagawa (JP); TAKANORI WATANABE, Kanagawa (JP); TATSUHITO GODEN, Tokyo (JP)

(21) Appl. No.: 18/926,807

(22) Filed: Oct. 25, 2024

(30) Foreign Application Priority Data
Nov. 7, 2023 (JP) 2023-190404
Jul. 4, 2024 (JP) 2024-108504

(51) Int. Cl. H01L 27/146

(52) U.S. Cl. CPC H10F 39/811; H10F 39/8023; H10F 39/8057

(57) ABSTRACT

A radiation detector includes a semiconductor substrate including a pixel portion and a peripheral circuit portion, and a mark portion having conductivity. In plan view, the mark portion is disposed in a first region or a third region among the first region, a second region, and the third region. The first region includes the pixel portion. The second region includes the peripheral circuit portion and is positioned outside the first region. The third region is positioned between the first region and the second region. The mark portion is connected to a predetermined potential.

### BACKGROUND

### Technical Field

The present disclosure relates to a radiation detector, a detection unit, and a radiation imaging system.

### Description of the Related Art

A radiation detector including a semiconductor substrate on which pixels and peripheral circuits are formed is known. When a radiation is incident on a peripheral circuit region, the radiation can cause erroneous operation of the peripheral circuits or malfunction of the peripheral circuits. Therefore, a shielding member that shields the radiation such that the radiation is not incident on the peripheral circuits is provided in the radiation detector. The shielding member has an opening provided at a position corresponding to a pixel region of the radiation detector. Therefore, the radiation detector and the shielding member need to be aligned such that the radiation is incident on the pixels through the opening of the shielding member.

In contrast, Japanese Patent Application Laid-Open No. 2021-48356 discloses an image sensor for light detection that is not configured to detect a radiation. Japanese Patent Application Laid-Open No. 2021-48356 discloses forming a mark used for an exposing step in manufacture of an image sensor or a mark used for an inspection step of the image sensor on the image sensor.

Although this does not cause a problem in the image sensor for light detection disclosed in Japanese Patent Application Laid-Open No. 2021-48356, in the case of a radiation detector that detects a radiation having an ionization effect such as an X-ray or an electron beam, there is a possibility that the mark portion is charged up when the mark portion having conductivity is irradiated with a radiation. In the case where charges in the charged mark portion are discharged to a circuit around the mark portion, there is a possibility that an erroneous operation or malfunction of the circuit occurs.

### SUMMARY

The present disclosure provides a technique advantageous for a stable operation of a radiation detector.

According to one aspect of the present disclosure, a radiation detector includes a semiconductor substrate including a pixel portion and a peripheral circuit portion, and a mark portion having conductivity. In plan view, the mark portion is disposed in a first region or a third region among the first region, a second region, and the third region. The first region includes the pixel portion. The second region includes the peripheral circuit portion and is positioned outside the first region. The third region is positioned between the first region and the second region. The mark portion is connected to a predetermined potential.

Further features of the present invention will become apparent from the following description of exemplary embodiments with reference to the attached drawings.

### BRIEF DESCRIPTION OF THE DRAWINGS

FIG. 1 is a schematic diagram illustrating a configuration of a radiation detector according to a first embodiment.

FIG. 2A is a plan view of the radiation detector according to the first embodiment.

FIG. 2B is an exploded perspective view of a detection unit according to the first embodiment.

FIG. 3A is a section view of the radiation detector according to the first embodiment.

FIG. 3B is an explanatory diagram of a mark portion according to the first embodiment.

FIG. 3C is an explanatory diagram of the mark portion according to the first embodiment.

FIG. 4 is a section view of a radiation detector according to a modification example of the first embodiment.

FIG. 5A is a plan view of a mark portion according to a second embodiment.

FIG. 5B is a section view of a radiation detector according to the second embodiment.

FIG. 6 is a section view of a radiation detector according to a third embodiment.

FIG. 7A is a plan view of a mark portion according to a fourth embodiment.

FIG. 7B is a section view of a radiation detector according to the fourth embodiment.

FIG. 8A is a plan view of a radiation detector according to a fifth embodiment.

FIG. 8B is a section view of the radiation detector according to the fifth embodiment.

FIG. 8C is a section view of the radiation detector according to the fifth embodiment.

FIG. 9 is a section view of a radiation detector according to a sixth embodiment.

FIG. 10A is a plan view of a radiation detector according to a seventh embodiment.

FIG. 10B is a section view of the radiation detector according to the seventh embodiment.

FIG. 11A is a plan view of a radiation detector according to an eighth embodiment.

FIG. 11B is a plan view of a detection unit according to the eighth embodiment.

FIG. 12A is a section view of a radiation detector according to a ninth embodiment.

FIG. 12B is a plan view for describing a connection state between a region of a mark portion and a pad electrode according to the ninth embodiment.

FIG. 13 is a section view of a radiation detector according to a tenth embodiment.

FIG. 14 is a section view of a radiation detector according to an eleventh embodiment.

FIG. 15A is a section view of a radiation detector according to a twelfth embodiment.

FIG. 15B is a plan view for describing a connection state between a region of a mark portion and a pad electrode according to the twelfth embodiment.

FIG. 16 is a diagram illustrating a system according to a thirteenth embodiment.

FIG. 17A is a diagram illustrating a system according to a fourteenth embodiment.

FIG. 17B is a diagram illustrating the system according to the fourteenth embodiment.

### DESCRIPTION OF THE EMBODIMENTS

Embodiments of the present disclosure will be described below with reference to drawings. To be noted, the present invention is not limited to the embodiments below, and can be appropriately modified within the gist thereof. In addition, in the drawings described below, elements having the same functions will be denoted by the same reference signs, and description thereof will be omitted.

In the description below, “radiation” is a concept including ionized radiations (X-ray and gamma ray) and particle beam radiations (electron beam, proton beam, neutron beam, alpha ray, and the like). “Radiation imaging system” generally refers to a system that obtains an image of an imaging target (object, patient in the case of a medical imaging system, and the like) as electronic data by using a radiation. The “image” may be a still image or a moving image. “Radiation detector” refers to an image sensor unit (also referred to as a camera or an imaging portion) that is a constituent element of a radiation imaging system and that obtains an image as electronic data by converting a radiation image of an imaging target into an electric signal.

### First Embodiment

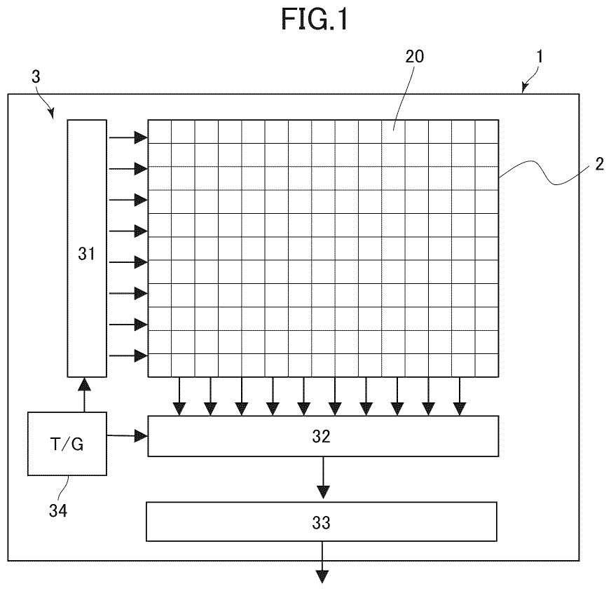

FIG. 1 is a schematic diagram illustrating a configuration of a radiation detector 1 according to a first embodiment. The radiation detector 1 is an image sensor, for example, a complementary metal oxide semiconductor (CMOS) image sensor. The radiation detector 1 includes a pixel array 2 serving as an example of a pixel portion, and a peripheral circuit portion 3.

The pixel array 2 includes a plurality of pixels 20 arranged in an array shape. The plurality of pixels 20 include effective pixels each including a detection diode. Each pixel 20 accumulates charges generated by a radiation that the pixel has received, and outputs a pixel signal (analog signal) corresponding to the amount of accumulated charges. To be noted, the plurality of pixels 20 may include non-effective pixels and/or dummy pixels. Here, the effective pixel is a pixel used for image generation, and is positioned in an effective pixel region (imaging region). The non-effective pixel is a pixel that is positioned in a region (non-effective pixel region) other than the effective pixel region, and is not used for image generation. The dummy pixel is a pixel not including a detection diode.

The peripheral circuit portion 3 includes a plurality of peripheral circuits. For example, the peripheral circuit portion 3 includes peripheral circuits such as a vertical scan circuit 31, a readout circuit 32, a signal output circuit 33, and a timing generator 34. The timing generator 34 controls the operation of each of the circuits 31 and 32 by a control signal. The vertical scan circuit 31 sequentially selects the pixels 20 of the pixel array 2 on a row basis. The readout circuit 32 includes an A/D conversion circuit, and converts a pixel signal, which is an analog signal read out from the pixel 20, into a digital signal. The signal output circuit 33 outputs the pixel signal converted into a digital signal to an external apparatus. To be noted, the peripheral circuit portion 3 may additionally include peripheral circuits such as a column amplifier, a correlated double sampling (CDS) circuit, and an adder circuit.

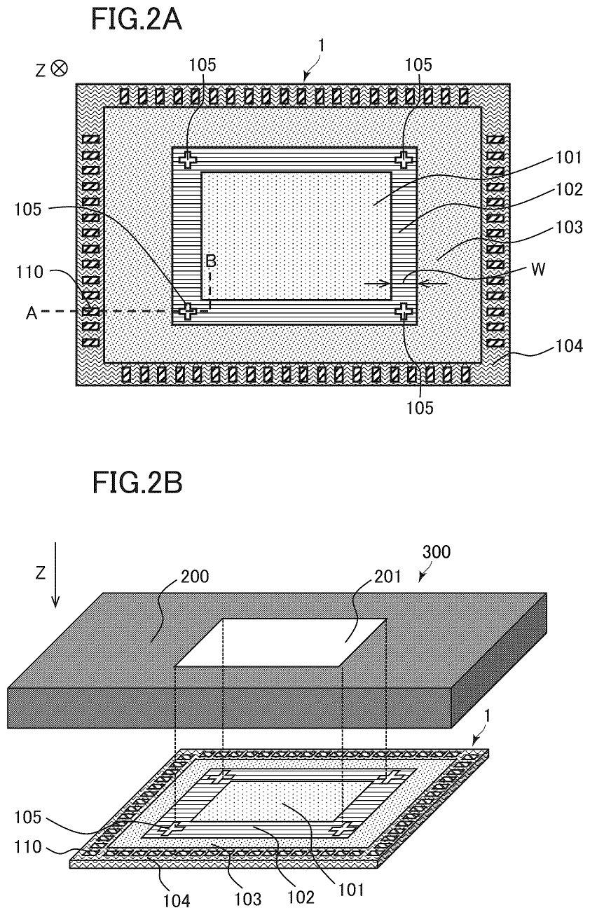

FIG. 2A is a plan view of the radiation detector 1 according to the first embodiment. FIG. 2A illustrates a surface (incident surface) on the radiation incident side of the radiation detector 1 in plan view, that is, as viewed in a Z direction. The Z direction is a direction orthogonal to the incident surface of the radiation detector 1, and is a direction toward the incident surface.

The radiation detector 1 is segmented into a plurality of regions as viewed in the Z direction. The plurality of regions include a pixel region 101, a buffer region 102, a peripheral circuit region 103, and a pad region 104. The pixel region 101 is a region including the pixel array 2. The peripheral circuit region 103 is a region including the peripheral circuit portion 3, and is a region positioned outside the pixel region 101. The buffer region 102 is a region between the pixel region 101 and the peripheral circuit region 103. The pad region 104 is a region positioned outside the peripheral circuit region 103. Neither the pixel array 2 nor the peripheral circuit portion 3 is present in the buffer region 102.

The pixel region 101 is a region having a rectangular shape. The buffer region 102 is a region having a quadrangular frame shape, and is adjacent to the pixel region 101 so as to surround the pixel region 101. The peripheral circuit region 103 is a region having a quadrangular frame shape, and is adjacent to the buffer region 102 so as to surround the buffer region 102. The pad region 104 is a region having a quadrangular frame shape, and is adjacent to the peripheral circuit region 103 so as to surround the peripheral circuit region 103. In the pad region 104, a plurality of pad electrodes 110 for electrically connecting to a driving board or the like including a power source (power source circuit) by wire bonding are provided. The pixel region 101 is an example of a first region. The peripheral circuit region 103 is an example of a second region. The buffer region 102 is an example of a third region.

At least one mark portion is disposed in the buffer region 102 as viewed in the Z direction. The at least one mark portion is preferably two or more mark portions. In the first embodiment, for example, four mark portions 105 are disposed as the at least one mark portion in the buffer region 102. Each mark portion 105 is disposed in the vicinity of corresponding one of four corner portions of the buffer region 102 as viewed in the Z direction. To be noted, the position of the mark portion 105 is not limited to the vicinity of a corner portion of the buffer region 102. For example, a plurality of mark portions may be disposed in a distributed manner all over the buffer region 102.

The pixel region 101 includes an isolation region and an active region. Further, the plurality of pixels 20 illustrated in FIG. 1 are two-dimensionally arranged in the pixel region 101.

Here, if a radiation is incident on the peripheral circuit region 103, there is a possibility that a peripheral circuit in the peripheral circuit portion 3 is charged up. In addition, there is a possibility that a defect occurs in a boundary between an insulating layer and a semiconductor substrate and the defects serves as a cause of dark current, a possibility that an electron generated by the radiation flows into a peripheral circuit to cause a latch-up, and the like. Due to these factors, there is a possibility that erroneous operation of a peripheral circuit or malfunction of a peripheral circuit occurs. Therefore, in the first embodiment, a shielding member shielding a radiation such that no radiation is incident on the peripheral circuits is provided in the radiation detector 1.

FIG. 2B is an exploded perspective view of a detection unit 300 according to the first embodiment. The detection unit 300 includes the radiation detector 1 and a shielding member 200. The shielding member 200 is formed from a metal member capable of shielding a radiation. The shielding member 200 is disposed on the radiation incident side of the radiation detector 1. The shielding member 200 is disposed at a position overlapping with the entirety of the peripheral circuit region 103, that is, the entirety of the peripheral circuit portion 3 illustrated in FIG. 1 as viewed in the Z direction such that no radiation is radiated onto the peripheral circuit region 103.

An opening 201 that is a through hole is provided in the shielding member 200. The opening 201 is formed at a position corresponding to the pixel array 2 such that the radiation is incident on the pixel array 2. The opening 201 has a rectangular shape having a larger area than the pixel region 101 as viewed in the Z direction. That is, the pixel array 2 disposed in the pixel region 101 does not overlap with the shielding member 200 as viewed in the Z direction. The pixel array 2 disposed in the pixel region 101 is irradiated with a radiation having passed through the opening 201 of the shielding member 200. The mark portion 105 is used for aligning the shielding member 200 with the radiation detector 1 such that the shielding member 200 does not overlap with the pixel array 2.

Here, misalignment, variation in the shape of the opening 201 of the shielding member 200, the radiation spreading through the opening 201 of the shielding member 200 to the peripheral circuit region 103, and the like need to be considered in the alignment between the radiation detector 1 and the shielding member 200. Therefore, the buffer region 102 serving as an alignment margin is provided between the pixel region 101 and the peripheral circuit region 103 in the radiation detector 1.

If it is easy to visually recognize and focus on the mark portion 105 in the measurement of the mark portion 105 for positioning the shielding member 200, the cost of a system for aligning the radiation detector 1 and the shielding member 200 can be reduced, or the precision of the system can be improved.

Increasing a width W of the buffer region 102 as viewed in the Z direction increases the alignment margin and facilitates the alignment between the radiation detector 1 and the shielding member 200, but this increases the size of the semiconductor substrate 100. In addition, increasing the width W of the buffer region 102 increases the length of the wiring for pixel signals and control signals between the pixel region 101 and the peripheral circuit region 103, which can lead to decrease in the communication speed of the signals. Therefore, by improving the alignment precision between the radiation detector 1 and the shielding member 200, the width W of the buffer region 102 can be reduced, which can lead to reduction of the manufacturing cost of the radiation detector 1 and increase in the communication speed of the signals.

In consideration of the scattering of the radiation incident on the radiation detector 1, the width W of the buffer region 102 is preferably 200 μm or more. In addition, in consideration of the communication speed of the pixel signal and the control signal in the buffer region 102, the width W of the buffer region 102 is preferably 2000 μm or less.

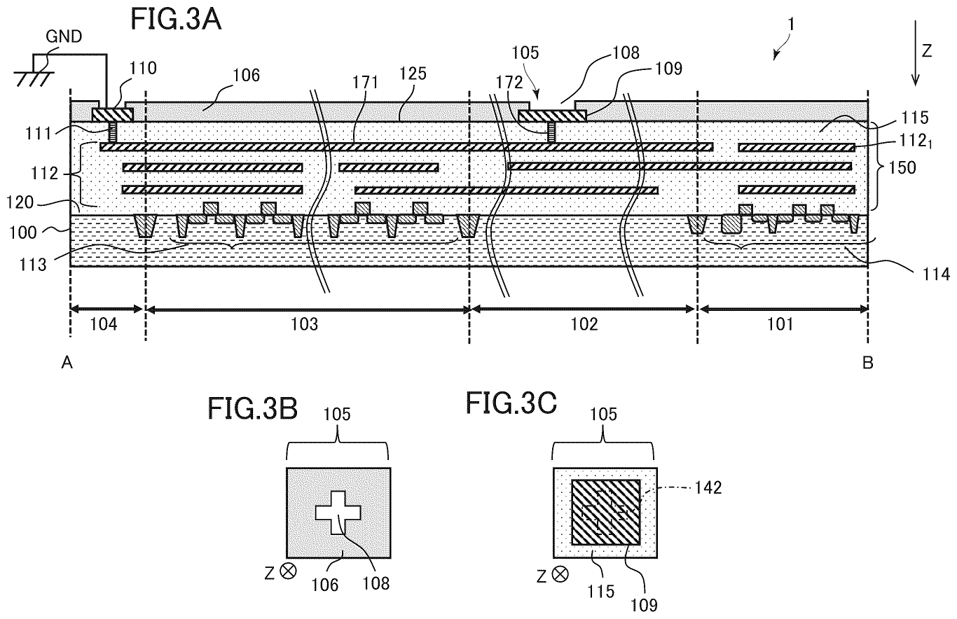

FIG. 3A is a section view of the radiation detector 1 taken along a line A-B of FIG. 2A. The radiation detector 1 includes the semiconductor substrate 100 and a wiring structure body 150 including an interlayer insulating layer 115 disposed on the semiconductor substrate 100 and formed from an insulator, and a plurality of wiring layers (conductor layers) 112 disposed in the interlayer insulating layer 115.

The semiconductor substrate 100 includes the pixel array 2 and the peripheral circuit portion 3 illustrated in FIG. 1. At least part of the pixel array 2 and the peripheral circuit portion 3 is formed on the semiconductor substrate 100.

In addition, a wiring pattern (conductor pattern) 109, a passivation layer 106, and the pad electrodes 110 are disposed on a main surface 125 of the interlayer insulating layer 115. The passivation layer 106 is adjacent to the wiring pattern 109 and the interlayer insulating layer 115, and is a layer protecting members of the radiation detector 1, for example, the wiring pattern 109 and the interlayer insulating layer 115. That is, the wiring pattern 109 is in contact with the main surface 125 of the interlayer insulating layer 115, and the passivation layer 106 is in contact with part of the main surface 125 of the interlayer insulating layer 115 that is not in contact with the wiring pattern 109.

Here, in a CMOS image sensor for light detection, there is a case where a color filter layer for color recognition and a microlens layer for light condensation on each pixel are disposed on the interlayer insulating layer. However, since the radiation detector 1 is used for detecting radiation, the color filter layer and the microlens layer do not need to be provided.

Examples of the material of the passivation layer 106 include organic insulating materials such as silicon oxide, silicon nitride, silicon oxynitride, and polyimide, and combinations of two or more of these materials. Examples of the material of the wiring pattern of each of the outermost wiring layer and the wiring layer 112 include copper, aluminum, tungsten, tantalum, titanium, polysilicon, and alloys including at least one of these metals. Examples of the material of the interlayer insulating layer 115 include silicon oxide, borophosphosilicate glass (BPSG), phosphosilicate glass (PSG), borosilicate glass (BSG), silicon nitride, silicon carbide, and combinations of two or more of these insulating materials.

Control signals such as a vertical signal, a reset signal, and a selection signal can be communicated through the wiring pattern 109, the pad electrodes 110, the wiring layers 112, vias 111, and vias 172. Part of wiring interconnecting the pixel array 2 and the peripheral circuit portion 3 is disposed in the buffer region 102. In addition, the mark portion 105 is disposed in the buffer region 102. The opening 201 of the shielding member 200 is positioned in accordance with the mark portions 105. Since there is a possibility that part of the buffer region 102 is irradiated with the radiation, the members provided in the buffer region 102 preferably have a resistance to irradiation with radiations.

The main surface 120 of the semiconductor substrate 100 is in contact with the interlayer insulating layer 115. A detection diode for detecting a radiation, and a transistor 114 configured to output a detection signal of the detection diode are disposed on the semiconductor substrate 100. In addition, a gate of the transistor 114 is disposed on a main surface 120 of the semiconductor substrate 100. The detection diode and the transistor 114 are included in each of the effective pixels and non-effective pixels among the plurality of pixels 20 (FIG. 1), and are positioned in the pixel region 101 as viewed in the Z direction.

To be noted, the structure of the pixel 20 may be a direct connection type constituted by three transistors, or a transfer type including four transistors in which connection to a gate electrode of an amplification transistor is established through a transistor that transfers charges accumulated in the diode. A structure having advantageous characteristics can be selected in accordance with the use of the radiation detector 1.

In addition, since the pixel region 101 is irradiated with a radiation, it is preferable that the transistors in the pixel region 101 are designed in consideration of radiation resistance. In addition, radiations have a nature of being transmitted through the wiring and the transistors. For example, in the case where the radiation is an electron beam, even if wiring or a transistor is disposed on the detection diode, the detection diode can detect the electron beam because the electron beam reaches the detection diode.

In addition, a transistor 113 constituting a peripheral circuit, for example, a signal processing circuit included in the peripheral circuit portion 3, is disposed on the semiconductor substrate 100, and the gate of the transistor 113 is disposed on the main surface 120 thereof. The transistor 113 is positioned in the peripheral circuit region 103 as viewed in the Z direction. As described above, the peripheral circuit portion 3 including a plurality of peripheral circuits is disposed in the peripheral circuit region 103, and the peripheral circuit portion 3 is shielded from the radiation by the shielding member 200 illustrated in FIG. 2B.

As described above, a plurality of pad electrodes 110 are disposed in the pad region 104. The pad electrodes 110 are disposed on the outermost wiring layer. In other words, the pad electrodes 110 and the wiring pattern 109 are disposed in the layer of the same height. The pad electrodes 110 are provided on the main surface 125 of the interlayer insulating layer 115 in correspondence with an opening of the passivation layer 106, and is electrically connected to a driving board or the like disposed on the outside of the radiation detector 1 through a wire. To be noted, the pad electrodes 110 may be, by using through wiring, electrically connected to the driving board from a surface on the side opposite to the side on which the passivation layer 106 is provided.

The mark portion 105 disposed in the buffer region 102 will be described. FIGS. 3B and 3C are explanatory diagrams of the mark portion 105. FIG. 3B is a plan view of a region of the passivation layer 106 including the mark portion 105 as viewed in the Z direction. FIG. 3C is a plan view of a region of the wiring pattern 109 and the interlayer insulating layer 115 including the mark portion 105 as viewed in the Z direction.

In the first embodiment, the mark portion 105 is a plus-shaped mark in plan view, that is, as viewed in the Z direction. The mark portion 105 has conductivity. In the first embodiment, the mark portion 105 is constituted by an opening 108 provided in the passivation layer 106, and the wiring pattern 109 constituting part of the outermost wiring layer. In the first embodiment, the opening 108 is a through hole penetrating the passivation layer 106. The opening 108 has a plus shape as viewed in the Z direction.

The wiring pattern 109 is a solid pattern having a larger area than the opening 108 as viewed in the Z direction. In the wiring pattern 109, a portion corresponding to the opening 108 constitutes the mark portion 105. In the wiring pattern 109, a region 142 visually recognized through the opening 108 constitutes the mark portion 105.

As described above, the mark portion 105 is a recess portion including the opening 108 of the passivation layer 106 and the wiring pattern 109 that is provided on the outermost wiring layer that is a lower layer adjacent to the passivation layer 106 and that is visually recognized through the opening 108. Here, the outermost wiring layer constitutes part of the outermost layer of the radiation detector 1.

A manufacturing method for the detection unit 300 illustrated in FIG. 2B will be described. First, the radiation detector 1 and the shielding member 200 are prepared.

Next, the mark portion 105 is measured by using a measurement apparatus such as a microscope from the incident surface side of the radiation detector 1. In the first embodiment, since the mark portion 105 serving as a standard for alignment is provided, the mark portion 105 can be easily optically measured, and the focus of the measurement apparatus can be also easily adjusted.

Next, the shielding member 200 is aligned with the radiation detector 1 such that the peripheral circuit region 103 of the radiation detector 1 is covered by the shielding member 200 as viewed in the Z direction. Specifically, the shielding member 200 and the radiation detector 1 are aligned such that the shielding member 200 overlaps with part or entirety of each mark portion 105 and the shielding member 200 does not overlap with the pixel array 2 (pixel region 101) as viewed in the Z direction, and then are each fixed. In the first embodiment, the shielding member 200 is aligned with the radiation detector 1 so as to overlap with the entirety of each mark portion 105.

At the time of this alignment, since the visibility of the mark portion 105 is high, the shielding member 200 can be aligned with the radiation detector 1 with high precision. For example, by aligning a corner of the opening 201 of the shielding member 200 with a corner of the mark portion 105 having a plus shape as illustrated in FIG. 2B, each mark portion 105 overlaps with the shielding member 200, and the shielding member 200 can be aligned with the radiation detector 1 with high precision.

As described above, according to the first embodiment, a technique advantageous for alignment between the radiation detector 1 and the shielding member 200 is provided. Further, since the visibility of the mark portion 105 is high, the shielding member 200 can be aligned with the radiation detector 1 with high precision.

In addition, as a result of the radiation being shielded by the shielding member 200, the radiation being incident on the peripheral circuit portion 3 in the peripheral circuit region 103 can be suppressed, the circuit of the peripheral circuit portion 3 being charged up can be suppressed, and malfunction of the circuit of the peripheral circuit portion 3 can be suppressed. In addition, in the peripheral circuit region 103, generation of a defect in the interface between the interlayer insulating layer 115 and the semiconductor substrate 100 can be reduced, and generation of a dark current can be reduced. As a result of this, the operation of the circuit of the peripheral circuit portion 3 is stabilized. In addition, electrons generated by irradiation with the radiation flowing to the circuit of the peripheral circuit portion 3 can be suppressed, and thus occurrence of erroneous operation such as a latch-up can be suppressed. As a result of this, the operation of the circuit of the peripheral circuit portion 3 is stabilized. In addition, since the pixel array 2 disposed in the pixel region 101 does not overlap with the shielding member 200 as viewed in the Z direction, occurrence of an image defect can be suppressed.

Even if a wide buffer region 102 is provided, since the mark portion 105 is disposed near the edge of the opening 201 of the shielding member 200, the radiation having passed through the opening 201 can be incident on the mark portion 105. The radiation incident on the mark portion 105 can include a component of the radiation spreading at the opening 201, a component of backward scattering coming back up after scattering on the inside of the radiation detector 1, and the like. If the wiring pattern 109 of the mark portion 105 is a floating potential, the wiring pattern 109 can be charged up by the radiation radiated onto the region 142 of the wiring pattern 109.

In the first embodiment, the wiring pattern 109 of the mark portion 105 is connected to a predetermined potential. The predetermined potential is a potential set in a power source or the like, and is a potential different from a floating potential. In the example of the first embodiment, the predetermined potential is a ground potential GND set by the power source.

The wiring pattern 109 of the mark portion 105 is connected to the ground potential GND through a wiring pattern 171. The plurality of wiring layers 112 disposed inside the interlayer insulating layer 115 at intervals therebetween in the Z direction include a wiring layer 112₁ adjacent to the wiring pattern 109 with the insulator of the interlayer insulating layer 115 therebetween. Here, the wiring pattern 109 is an example of a first wiring pattern, and the wiring layer 112₁ is an example of a wiring layer in which a second wiring pattern is disposed. The wiring layer 112₁ is a wiring layer adjacent to the wiring pattern 109 with the insulator of the interlayer insulating layer 115 therebetween and positioned between the wiring pattern 109 and the semiconductor substrate 100.

In the first embodiment, the wiring layer 112₁ includes the wiring pattern 171 overlapping with the wiring pattern 109 and a pad electrode 110 as viewed in the Z direction. The wiring pattern 171 extends from at least the buffer region 102 to the pad region 104. The wiring pattern 109 and the pad electrode 110 are electrically interconnected by the wiring pattern 171, a via 172 interconnecting the wiring pattern 109 and the wiring pattern 171, and a via 111 interconnecting the pad electrode 110 and the wiring pattern 171. Further, the pad electrode 110 is connected to the power source through a wire.

As a result of the mark portion 105 being connected to the ground potential GND, the charges generated by the charge-up are discharged to the outside (power source) through the via 172, the wiring pattern 171, the via 111, and the pad electrode 110 even if the wiring pattern 109 is charged by the irradiation with the radiation. Therefore, the charge-up of the mark portion 105 is reduced. As a result of this, operation failure and malfunction of circuits included in the radiation detector 1, for example, the peripheral circuit portion 3 can be suppressed.

As described above, according to the first embodiment, the charge-up of the mark portion 105 can be reduced, and operation failure and malfunction of the radiation detector 1 can be suppressed. As described above, according to the first embodiment, a technique advantageous for stable operation of the radiation detector 1 can be provided.

### Modification Example of First Embodiment

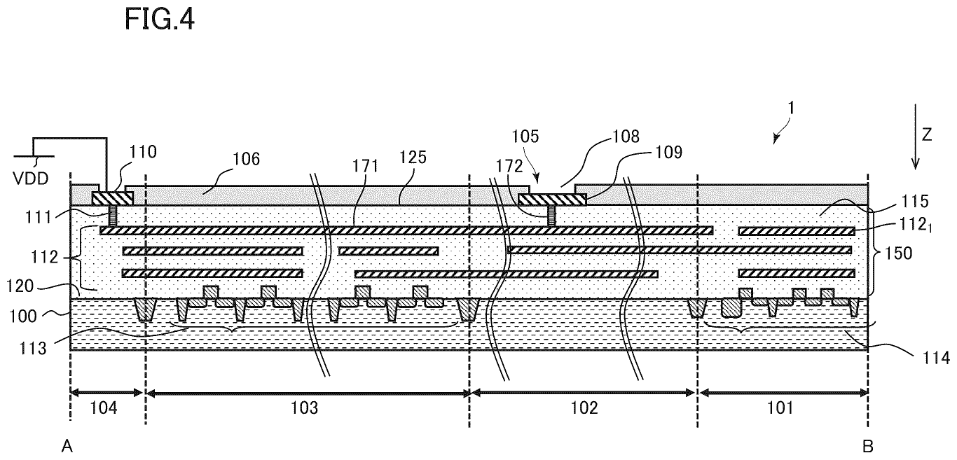

A modification example of the predetermined potential to which the mark portion 105 is connected will be described. FIG. 4 is a section view of the radiation detector 1 according to the modification example. FIG. 4 schematically illustrates a section view of the radiation detector 1 taken along a line A-B of FIG. 2A.

Although a case where the mark portion 105 is connected to the ground potential GND has been described in the first embodiment, the configuration is not limited to this. For example, the mark portion 105 may be connected to a power source potential VDD of a driving power source for driving the radiation detector 1. In addition, the power source potential VDD may be a potential directly output from the power source, or a potential generated by raising or lowering the potential output from the power source. The raising or lowering may be performed by a circuit outside the radiation detector 1. In addition, the raising or lowering may be performed by a circuit included in the radiation detector 1. That is, the power source potential VDD may be an internal potential generated inside the radiation detector 1.

In addition, the driving power source is a direct current constant voltage source, and the value of the power source potential VDD is constant over time. To be noted, the power source is not limited to a constant voltage source, and may be a variable voltage source capable of adjusting the power source potential VDD. The variable voltage source can include a switching power source whose potential switches over time.

In addition, the predetermined potential to which the mark portion 105 is connected may be a potential of a power source different from the driving power source used for driving the radiation detector 1. For example, in the case of intending to enhance the charge discharging effect of the charged mark portion 105, the potential to which the mark portion 105 is connected may be a potential higher than the driving power source potential VDD. In the case where the charges with which the mark portion 105 is charged are electrons, the potential to which the mark portion 105 is connected is preferably a positive potential. In the case where the charges with which the mark portion 105 is charged are holes, the holes have lower mobility than electrons. Therefore, in this case, a negative potential may be applied to remove the holes. In the case of a variable voltage source, the predetermined potential may be switched between a positive potential and a negative potential in accordance with the polarity of the charges.

### Second Embodiment

A radiation detector according to a second embodiment will be described with reference to drawings. In the second embodiment, description of matter common to the first embodiment will be simplified or omitted, and difference from the first embodiment will be mainly described. The schematic configuration of the radiation detector 1 of the second embodiment is as described in the first embodiment with reference to FIGS. 1 and 2A. In addition, the schematic configuration of the detection unit 300 including the radiation detector 1 and the shielding member 200 of the second embodiment is as described in the first embodiment with reference to FIG. 2B.

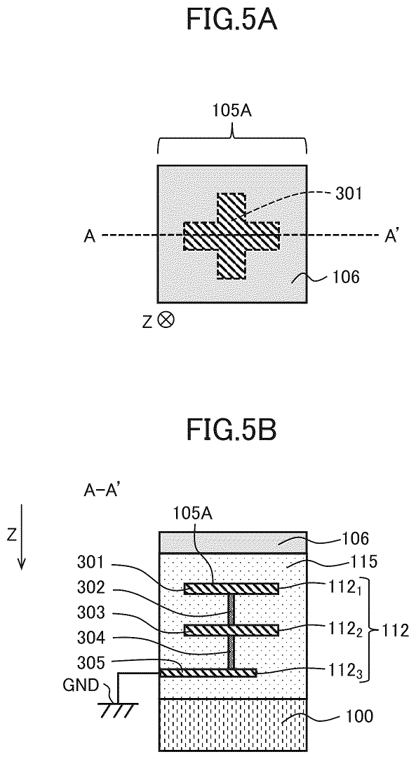

FIG. 5A is a plan view of a mark portion 105A according to the second embodiment, and FIG. 5B is a section view of the radiation detector 1 taken along a line A-A′ of FIG. 5A. In the second embodiment, the mark portion 105A is constituted by one of the plurality of wiring layers 112 disposed inside the interlayer insulating layer 115.

For example, the plurality of wiring layers 112 include wiring layers 112₁, 112₂, and 112₃ disposed at intervals in the Z direction. The wiring layer 112₂ is closer to the semiconductor substrate 100 than the wiring layer 112₁. The wiring layer 112₃ is closer to the semiconductor substrate 100 than the wiring layer 112₂. That is, the distance between the wiring layer 112₂ and the semiconductor substrate 100 in the Z direction is smaller than the distance between the wiring layer 112₁ and the semiconductor substrate 100 in the Z direction. In addition, the distance between the wiring layer 112₃ and the semiconductor substrate 100 in the Z direction is smaller than the distance between the wiring layer 112₂ and the semiconductor substrate 100 in the Z direction. The mark portion 105A is a wiring pattern 301 disposed in the wiring layer 112₁ farthest from the semiconductor substrate 100 among the wiring layers 112₁ to 112₃.

In the second embodiment, the wiring layer 112₁ is an example of a first wiring layer, and the wiring layer 112₂ is an example of a second wiring layer. That is, the wiring layer 112₂ is adjacent to the wiring layer 112₁ with the insulator of the interlayer insulating layer 115 therebetween, and positioned between the wiring layer 112₁ and the semiconductor substrate 100. In addition, the wiring pattern 301 is an example of a first wiring pattern.

The wiring pattern 301 is a wiring pattern isolated from other wiring patterns in the wiring layer 112₁, and functions as a mark. In addition, as viewed in the Z direction, the wiring pattern 301 does not overlap with the wiring pattern 109 constituting part of the outermost wiring layer of the first embodiment. In addition, the passivation layer 106 and the interlayer insulating layer 115 transmits light of a wavelength range of visible light. That is, the passivation layer 106 and the interlayer insulating layer 115 are transparent or translucent for the wavelength range of visible light. Therefore, since the light passes through the passivation layer 106, the mark portion 105A can be visually recognized in the light measurement even if the passivation layer 106 overlaps with the interlayer insulating layer 115 in the Z direction as illustrated in FIG. 5B.

The wiring pattern 301 serving as the mark portion 105A is connected to the ground potential GND. As illustrated in FIG. 5B, the wiring pattern 301 is connected to the ground potential GND through wiring including a wiring pattern 303 disposed in the wiring layer 112₂ and a wiring pattern 305 disposed in the wiring layer 112₃. Further, the wiring includes a via 302 interconnecting the wiring pattern 301 (mark portion 105A) and the wiring pattern 303, and a via 304 interconnecting the wiring pattern 303 and the wiring pattern 305. Further, the wiring pattern 305 is connected to the pad electrode 110 illustrated in FIG. 3A through a via. As a result of this, the mark portion 105A is electrically connected to the pad electrode 110. The pad electrode 110 is connected to the ground potential GND of the power source. As a result of this, the mark portion 105A is connected to the ground potential GND.

In the second embodiment, the opening 108 illustrated in FIG. 2A does not have to be provided at a position corresponding to the wiring pattern 301 in the passivation layer 106. Therefore, the coverage of the passivation layer 106 can be increased, and thus the reliability of the radiation detector 1 can be improved.

In addition, depending on the material of each of the passivation layer 106 and the interlayer insulating layer 115, the contrast between the mark portion 105A and members therearound can be improved more in the case where the edges of the mark portion 105A are formed by patterning of the conductor of the wiring layer 112₁. Therefore, depending on the material of each of the passivation layer 106 and the interlayer insulating layer 115, the visibility of the mark portion 105A can be improved more than in the case where the edges of the mark portion 105A are defined by the opening 108 of the passivation layer 106 as in the first embodiment.

In addition, in the second embodiment, the wiring pattern 303 is formed at a position overlapping with the mark portion 105A as viewed in the Z direction. Further, the wiring pattern 303 is formed in a size and shape to be hidden under the mark portion 105A as viewed in the Z direction. As a result of this, the wiring pattern 303 positioned behind the mark portion 105A is less visually recognizable, and thus the visibility of the mark portion 105A is improved.

In addition, in the second embodiment, the wiring pattern 303 is formed in the same size and shape as the mark portion 105A as viewed in the Z direction. As a result of this, the electrical resistance of the wiring pattern 303 can be reduced, and thus the charge discharging effect in the case where the mark portion 105A is charged can be improved.

The vias 302 and 304 are formed at positions overlapping with the mark portion 105A as viewed in the Z direction. Further, the vias 302 and 304 are formed in sizes and shapes to be hidden under the mark portion 105A as viewed in the Z direction, for example, have columnar shapes having approximately circular cross-section in a direction orthogonal to the Z direction. As a result of this, the vias 302 and 304 positioned behind the mark portion 105A are less visually recognizable, and thus the visibility of the mark portion 105A is improved.

To be noted, various modifications can be made to the mark portion 105A of the second embodiment similarly to the first embodiment and modification examples thereof.

### Third Embodiment

A radiation detector according to a third embodiment will be described with reference to drawings. In the third embodiment, description of matter common to the first or second embodiment will be simplified or omitted, and difference from the first or second embodiment will be mainly described. The schematic configuration of the radiation detector 1 of the third embodiment is as described in the first embodiment with reference to FIGS. 1 and 2A. In addition, the schematic configuration of the detection unit 300 including the radiation detector 1 and the shielding member 200 of the third embodiment is as described in the first embodiment with reference to FIG. 2B.

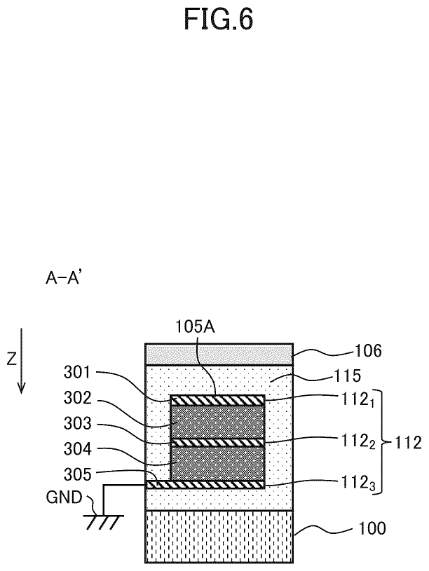

FIG. 6 is a section view of the radiation detector 1 taken along the line A-A′ of FIG. 5A. The radiation detector 1 includes the mark portion 105A configured in a similar manner to the second embodiment. The configuration of the vias 302 and 304 for connecting the mark portion 105A to the ground potential GND is different from the second embodiment.

The vias 302 and 304 are formed at positions overlapping with the mark portion 105A as viewed in the Z direction. Further, the vias 302 and 304 are formed in sizes and shapes to be hidden under the mark portion 105A as viewed in the Z direction. As a result of this, the vias 302 and 304 positioned behind the mark portion 105A are less visually recognizable, and thus the visibility of the mark portion 105A is improved.

In addition, in the third embodiment, the vias 302 and 304 are formed in the same size and shape as the mark portion 105A as viewed in the Z direction. As a result of this, the electrical resistance of the vias 302 and 304 can be reduced, and thus the charge discharging effect in the case where the mark portion 105A is charged can be improved.

To be noted, various modifications can be made to the mark portion 105A of the third embodiment similarly to the first and second embodiments and modification examples thereof.

### Fourth Embodiment

A radiation detector according to a fourth embodiment will be described with reference to drawings. In the fourth embodiment, description of matter common to any of the first to third embodiments will be simplified or omitted, and difference from the first to third embodiments will be mainly described. The schematic configuration of the radiation detector 1 of the fourth embodiment is as described in the first embodiment with reference to FIGS. 1 and 2A. In addition, the schematic configuration of the detection unit 300 including the radiation detector 1 and the shielding member 200 of the fourth embodiment is as described in the first embodiment with reference to FIG. 2B.

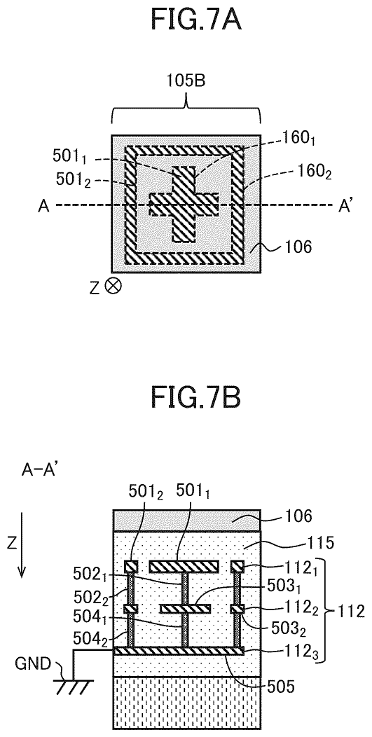

FIG. 7A is a plan view of a mark portion 105B according to the fourth embodiment, and FIG. 7B is a section view of the radiation detector 1 taken along a line A-A′ of FIG. 7A. In the fourth embodiment, the mark portion 105B is constituted by wiring patterns 501₁ and 501₂ disposed in the wiring layer 112₁ positioned inside the interlayer insulating layer 115. The mark portion 105B includes a mark 160₁ having a plus shape as viewed in the Z direction, and a mark 160₂ having a quadrangular frame shape surrounding the plus-shaped mark 160₁ as viewed in the Z direction. The mark portion 160₁ is disposed on the inner side of the mark 160₂ as viewed in the Z direction. The mark 160₁ of the mark portion 105B is the wiring pattern 501₁ disposed in the wiring layer 112₁. The mark 160₂ of the mark portion 105B is the wiring pattern 501₂ disposed in the wiring layer 112₁.

In the fourth embodiment, the wiring layer 112₁ is an example of a first wiring layer, and the wiring layer 112₂ is an example of a second wiring layer. That is, the wiring layer 112₂ is adjacent to the wiring layer 112₁ with the insulator of the interlayer insulating layer 115 therebetween, and positioned between the wiring layer 112₁ and the semiconductor substrate 100. In addition, the wiring pattern 501₁ is an example of a first wiring pattern.

When aligning the shielding member 200 with the radiation detector 1, the wiring pattern 501₂ having a frame shape is measured at a low magnification ratio, and thus the shielding member 200 is aligned with the radiation detector 1 with low precision. Then, the wiring pattern 501₁ having a plus shape is measured at a high magnification ratio, and thus the shielding member 200 is aligned with the radiation detector 1 with high precision. Then, the shielding member 200 is fixed to a module including the radiation detector 1, and thus the detection unit 300 is manufactured.

The wiring pattern 501₁ is a wiring pattern isolated from other wiring patterns in the wiring layer 112₁, and functions as the mark 160₁. The wiring pattern 501₂ is a wiring pattern isolated from other wiring patterns in the wiring layer 112₁, and functions as the mark 160₂.

The wiring pattern 501₁ serving as the mark 160₁ and the wiring pattern 501₂ serving as the mark 160₂ are connected to the ground potential GND.

As illustrated in FIG. 7B, the wiring patterns 501₁ and 501₂ are electrically connected to a wiring pattern 505 disposed in the wiring layer 112₃. The wiring pattern 501₁ is connected to the ground potential GND through wiring including a wiring pattern 503₁ disposed in the wiring layer 112₂ and the wiring pattern 505 disposed in the wiring layer 112₃. In addition, the wiring pattern 501₂ is connected to the ground potential GND through wiring including a wiring pattern 503₂ disposed in the wiring layer 112₂ and the wiring pattern 505 disposed in the wiring layer 112₃. Further, the wiring includes a via 502₁ interconnecting the wiring pattern 501₁ and the wiring pattern 503₁, and a via 504₁ interconnecting the wiring pattern 503₁ and the wiring pattern 505. Further, the wiring includes a wiring pattern 503₂ disposed in the wiring layer 112₂, a via 502₂ interconnecting the wiring pattern 501₂ and the wiring pattern 503₂, and a via 504₂ interconnecting the wiring pattern 503₂ and the wiring pattern 505.

As described above, the wiring patterns 501₁ and 501₂ are electrically connected to the wiring pattern 505. Further, the wiring pattern 505 is connected to the pad electrode 110 illustrated in FIG. 3A through a via. As a result of this, the marks 160₁ and 160₂ of the mark portion 105B are electrically connected to the pad electrode 110. The pad electrode 110 is connected to the ground potential GND of the power source. As a result of this, the mark portion 105B is connected to the ground potential GND.

In the fourth embodiment, the opening 108 illustrated in FIG. 2A does not have to be provided at a position corresponding to the wiring patterns 501₁ and 501₂ in the passivation layer 106. Therefore, the coverage of the passivation layer 106 can be increased, and thus the reliability of the radiation detector 1 can be improved.

In addition, in the fourth embodiment, the wiring pattern 503₁ is formed at a position overlapping with the wiring pattern 501₁ as viewed in the Z direction. Further, the wiring pattern 503₁ is formed in a size and shape to be hidden under the wiring pattern 501₁ as viewed in the Z direction. As a result of this, the wiring pattern 503₁ positioned behind the wiring pattern 501₁ is less visually recognizable, and thus the visibility of the wiring pattern 501₁ constituting the mark portion 105B is improved.

In addition, in the fourth embodiment, the wiring pattern 503₂ is formed at a position overlapping with the wiring pattern 501₂ as viewed in the Z direction. Further, the wiring pattern 503₂ is formed in a size and shape to be hidden under the wiring pattern 501₂ as viewed in the Z direction. As a result of this, the wiring pattern 503₂ positioned behind the wiring pattern 501₂ is less visually recognizable, and thus the visibility of the wiring pattern 501₂ constituting the mark portion 105B is improved.

The vias 502₁ and 504₁ are formed at positions overlapping with the wiring pattern 501₁ as viewed in the Z direction. Further, the vias 502₁ and 504₁ are formed in sizes and shapes to be hidden under the wiring pattern 501₁ as viewed in the Z direction, for example, have columnar shapes having approximately circular cross-section in a direction orthogonal to the Z direction. As a result of this, the vias 502₁ and 504₁ positioned behind the wiring pattern 501₂ are less visually recognizable, and thus the visibility of the mark 160₁ is improved.

The vias 502₂ and 504₂ are formed at positions overlapping with the wiring pattern 5012 as viewed in the Z direction. Further, the vias 502₂ and 504₂ are formed in sizes and shapes to be hidden under the wiring pattern 501₂ as viewed in the Z direction, for example, have columnar shapes having approximately circular cross-section in a direction orthogonal to the Z direction. As a result of this, the vias 502₂ and 504₂ positioned behind the wiring pattern 501₂ are less visually recognizable, and thus the visibility of the mark 160₂ is improved.

In the fourth embodiment, the plurality of wiring patterns 501₁ and 501₂ apart from each other constitute the mark portion 105B as illustrated in FIG. 7B, and the mark portion 105B can be electrically connected to the wiring pattern 505. Therefore, the charges in the charged mark portion 105B can be collectively discharged to the ground potential GND.

To be noted, various modifications can be made to the mark portion 105B of the fourth embodiment similarly to the first to third embodiments and modification examples thereof.

### Fifth Embodiment

A radiation detector according to a fifth embodiment will be described with reference to drawings. In the fifth embodiment, description of matter common to any of the first to fourth embodiments will be simplified or omitted, and difference from the first to fourth embodiments will be mainly described. The schematic configuration of the radiation detector 1 of the fifth embodiment is as described in the first embodiment with reference to FIGS. 1 and 2A. In addition, the schematic configuration of the detection unit 300 including the radiation detector 1 and the shielding member 200 of the fifth embodiment is as described in the first embodiment with reference to FIG. 2B. In the fifth embodiment, one or more mark portions and one or more mark portions among a plurality of mark portions are each connected to a different potential.

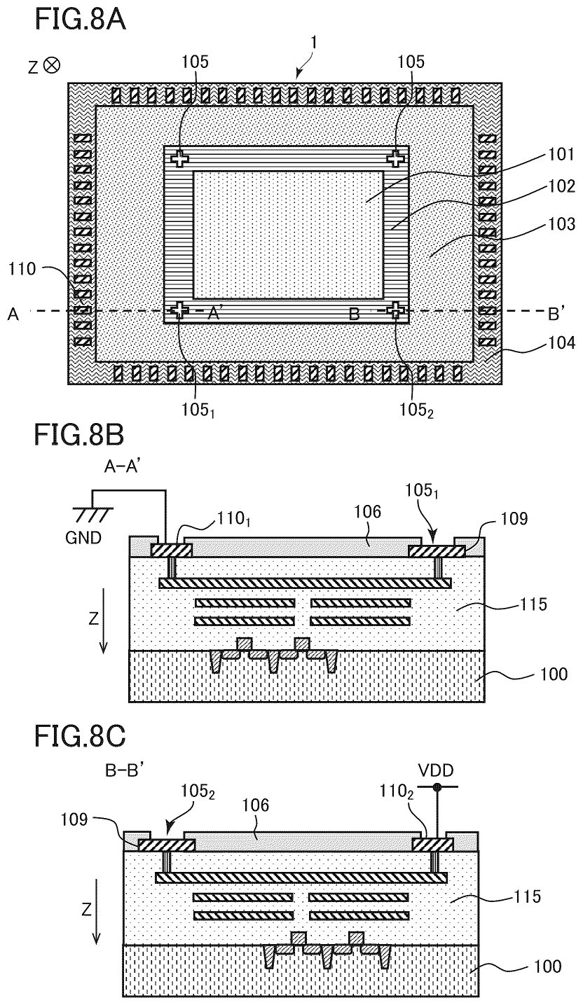

FIG. 8A is a plan view of the radiation detector 1 according to the fifth embodiment. FIG. 8B is a section view of the radiation detector 1 taken along a line A-A′ of FIG. 8A. FIG. 8C is a section view of the radiation detector 1 taken along a line B-B′ of FIG. 8A. Among the four mark portions 105 illustrated in FIG. 8A, two or more mark portions are respectively connected to two or more predetermined potentials different from each other. For example, among two mark portions 105₁ and 105₂, the mark portion 105₁ is connected to the ground potential GND, and the mark portion 105₂ is connected to the power source potential VDD. To be noted, the mark portions 105₁ and 105₂ each have a configuration similar to that of the mark portion 105 described in the first embodiment.

The mark portion 105₁ includes the wiring pattern 109 disposed in the outermost wiring layer. the wiring pattern 109 of the mark portion 105₁ is connected to the ground potential GND. The mark portion 105₂ includes the wiring pattern 109 disposed in the outermost wiring layer. The wiring pattern 109 of the mark portion 105₂ is connected to the power source potential VDD.

A pad electrode 110₁ is connected to the ground potential GND of the power source through a wire. A pad electrode 110₂ is connected to the power source potential VDD of the power source through a wire.

As a result of the mark portion 105₁ being connected to the pad electrode 110₁ that is relatively close thereto and the mark portion 105₂ being connected to the pad electrode 110₂ that is relatively close thereto, the degree of freedom of the wiring layout is improved. Further, since the length of each line of the wiring can be reduced, the impedance of the wiring can be reduced, and thus the charges in the mark portions 105₁ and 105₂ can be efficiently discharged.

In addition, in the fifth embodiment, the ground potential GND is applied to the pad electrode 110₁, the power source potential VDD is applied to the pad electrode 110₂, and thus charges can be discharged in both cases of charges of electrons and holes.

To be noted, the power source potential VDD is not limited to a fixed potential. For example, the power source potential VDD may be changed in accordance with the use, and the polarity thereof may be switched between a positive polarity and a negative polarity.

To be noted, various modifications can be made to the mark portions 105₁ and 105₂ of the fifth embodiment similarly to the first to fourth embodiments and modification examples thereof.

### Sixth Embodiment

A radiation detector according to a sixth embodiment will be described with reference to drawings. In the sixth embodiment, description of matter common to any of the first to fifth embodiments will be simplified or omitted, and difference from the first to fifth embodiments will be mainly described. The schematic configuration of the radiation detector 1 of the sixth embodiment is as described in the first embodiment with reference to FIGS. 1 and 2A. In addition, the schematic configuration of the detection unit 300 including the radiation detector 1 and the shielding member 200 of the sixth embodiment is as described in the first embodiment with reference to FIG. 2B.

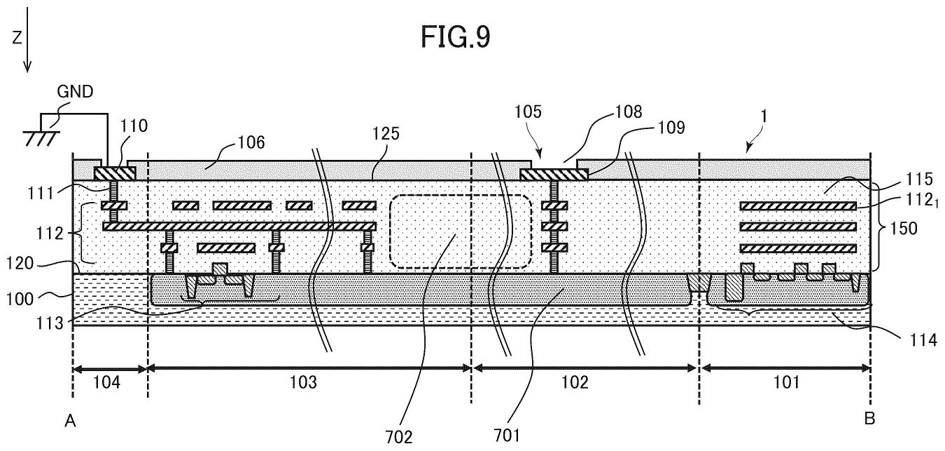

FIG. 9 is a section view of the radiation detector 1 taken along the line A-B of FIG. 2A. In the sixth embodiment, the mark portion 105 is connected to the ground potential GND at least via a well 701 included in the semiconductor substrate 100. Specifically, the mark portion 105 is connected to the ground potential GND via the wiring and the well 701. The well 701 is, for example, a well disposed to extend through the buffer region 102, the peripheral circuit region 103, and the pad region 104.

The wiring includes a plurality of wiring patterns disposed in the wiring layer 112, a plurality of vias interconnecting the plurality of wiring patterns and the wiring pattern 109 constituting the mark portion 105, and a via 111 interconnecting one of the wiring patterns in the wiring layer 112 and the pad electrode 110. In addition, the wiring is connected to the well 701 via a contact plug interconnecting the semiconductor substrate and a wiring pattern. In this manner, the mark portion 105 is connected to the ground potential GND via the well 701 and the wiring.

The well 701 may be configured as an N-well in the case where the potential applied to the pad electrode 110 is the ground potential GND. To be noted, the well 701 may be configured as a P-well in the case where the potential applied to the pad electrode 110 is the power source potential VDD.

According to the sixth embodiment, since the charges in the charged mark portion 105 can be received by the substrate capacitance, the endurance of the radiation detector 1 in the case where a large amount of charges are instantaneously generated can be improved. In addition, since the mark portion 105 is connected to the ground potential GND via the well 701, wiring for different use can be freely arranged in a region 702 in the interlayer insulating layer 115 positioned above the well 701.

To be noted, although a case where the mark portion 105 is connected to the ground potential GND via the well 701 disposed in the peripheral circuit region 103 has been described as an example, the mark portion 105 may be connected to the ground potential GND via a well in the pixel region 101.

To be noted, various modifications can be made to the mark portion 105 of the sixth embodiment similarly to the first to fifth embodiments and modification examples thereof.

### Seventh Embodiment

A radiation detector according to a seventh embodiment will be described with reference to drawings. In the seventh embodiment, description of matter common to any of the first to sixth embodiments will be simplified or omitted, and difference from the first to sixth embodiments will be mainly described. The schematic configuration of the radiation detector 1 of the seventh embodiment is as described in the first embodiment with reference to FIG. 1. In addition, the schematic configuration of the detection unit 300 including the radiation detector 1 and the shielding member 200 of the seventh embodiment is as described in the first embodiment with reference to FIG. 2B.

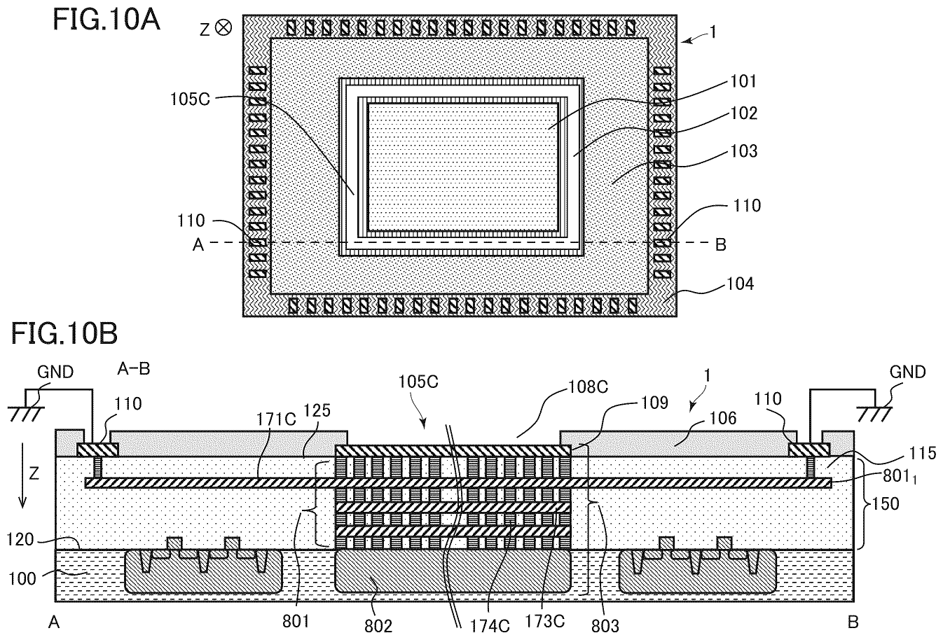

FIG. 10A is a plan view of the radiation detector 1 according to the seventh embodiment. FIG. 10B is a section view of the radiation detector 1 taken along a line A-B of FIG. 10A. The radiation detector 1 of the seventh embodiment includes a mark portion 105C disposed on the wiring structure body 150. The mark portion 105C is a mark portion disposed to surround the pixel region 101 (pixel array 2 of FIG. 1) in plan view, that is, as viewed in the Z direction. The mark portion 105C has conductivity. In the seventh embodiment, the mark portion 105C is constituted by an opening 108C of the passivation layer 106, and the wiring pattern 109 of the outermost wiring layer. In the seventh embodiment, the opening 108C is a through hole penetrating the passivation layer 106. The opening 108C has a quadrangular frame shape as viewed in the Z direction. The wiring pattern 109 can be visually recognized through the opening 108C.

The wiring pattern 109 of the mark portion 105C is connected to the ground potential GND. A plurality of wiring layers 801 arranged at intervals in the Z direction are included in the interlayer insulating layer 115. The plurality of wiring layers 801 include a wiring layer 801₁ adjacent to the wiring pattern 109 with the insulator of the interlayer insulating layer 115 therebetween. Here, the outermost wiring layer is an example of a first wiring layer, and the wiring layer 801₁ is an example of a second wiring layer. The wiring layer 801₁ is a wiring layer adjacent to the wiring pattern 109 with the insulator of the interlayer insulating layer 115 therebetween and positioned between the outermost wiring layer and the semiconductor substrate 100. The wiring pattern 109 is an example of a first wiring pattern.

In the seventh embodiment, the wiring layer 801₁ includes the wiring pattern 109 and a wiring pattern 171C overlapping with pad electrodes 110 as viewed in the Z direction. The wiring pattern 171C extends at least from the buffer region 102 to the pad region 104, and is connected to the pad electrodes 110 through vias.

As a result of the mark portion 105C being connected to the ground potential GND, the charges generated by the charge-up are discharged to the outside (power source) through the wiring even if the wiring pattern 109 of the mark portion 105C is charged by the irradiation with the radiation. Therefore, the charge-up of the mark portion 105C is reduced. As a result of this, operation failure and malfunction of circuits included in the radiation detector 1, for example, the peripheral circuit portion 3 can be suppressed.

In the seventh embodiment, a conductive ring structure 803 surrounding the pixel region 101 as viewed in the Z direction is disposed under the mark portion 105C. The ring structure 803 is formed in a quadrangular frame shape surrounding the outer periphery of the pixel region 101 as viewed in the Z direction.

The wiring pattern 109 of the mark portion 105C is also formed in a quadrangular frame shape as viewed in the Z direction. In addition, the wiring includes a plurality of wiring patterns 173C each formed in a quadrangular frame shape as viewed in the Z direction and disposed in the plurality of wiring layers 801 under the outermost wiring layer, and a plurality of vias 174C disposed along the quadrangular frame as viewed in the Z direction. The plurality of wiring patterns 173C can include the wiring pattern 171C connected to the ground potential GND. Further, a well 802 included in the semiconductor substrate 100 is also formed in a quadrangular frame shape surrounding the outer periphery of the pixel region 101.

In the seventh embodiment, the vias 174C interconnecting the plurality of wiring patterns 173C are each a columnar structure. In this case, the vias 174C are preferably provided in a high occupation ratio. Alternatively, the via 174C may be formed as a solid pattern similarly to the wiring patterns 173C of the wiring layers 801. The shape of the via 174C may be determined in consideration of the planarization process in the semiconductor process. The wiring pattern 109 having a quadrangular frame shape, the wiring patterns 173C having a quadrangular frame shape and included in the wiring layer 801, the vias 174C disposed along the quadrangular frame, and the well 802 constitute the ring structure 803. That is, the wiring and the well 802 are connected.

The ring structure 803 spatially separate the outside (peripheral circuit region 103 side) and the inside (pixel region 101 side) of the ring structure 803 from each other as viewed in the Z direction. As a result of this, even in the case where an electromagnetic noise is generated on the outside, the electric field derived from the noise is shielded by the ring structure 803, and therefore influence on the pixels 20 (FIG. 1) positioned in the pixel region 101 provided on the inside can be reduced. That is, the operation of the pixels 20 is stabilized by shielding the electromagnetic noise from the outside.

To be noted, although a case where the ring structure 803 includes the well 802, that is, a case where the wiring is connected to the well 802 has been described, the well 802 may be omitted in the ring structure 803. That is, the wiring does not have to be connected to the well 802.

To be noted, various modifications can be made to the mark portion 105C of the seventh embodiment similarly to the first to sixth embodiments and modification examples thereof.

### Eighth Embodiment

A radiation detector according to an eighth embodiment will be described with reference to drawings. In the eighth embodiment, description of matter common to the first embodiment will be simplified or omitted, and difference from the first embodiment will be mainly described.

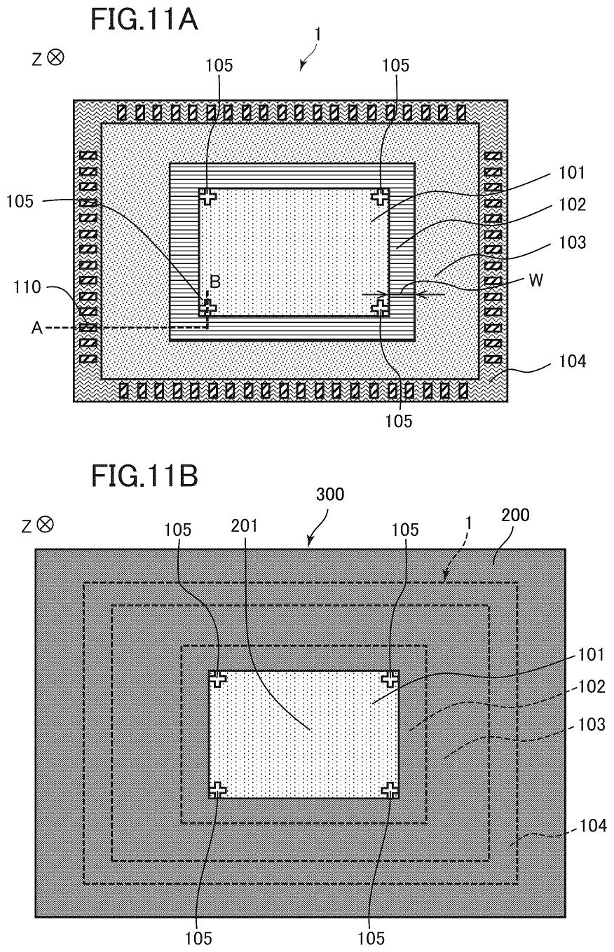

FIG. 11A is a plan view of the radiation detector 1 according to the eighth embodiment. FIG. 11A illustrates a surface (incident surface) on the radiation incident side of the radiation detector 1 in plan view, that is, as viewed in the Z direction. To be noted, the circuit configuration of the radiation detector 1 of the eighth embodiment is as described in the first embodiment with reference to FIG. 1.

The radiation detector 1 is segmented into a plurality of regions as viewed in the Z direction. The plurality of regions include the pixel region 101, the buffer region 102, the peripheral circuit region 103, and the pad region 104 similarly to the first embodiment. The pixel region 101 is an example of a first region. The peripheral circuit region 103 is an example of a second region. The buffer region 102 is an example of a third region. A plurality of mark portions, for example, four mark portions 105 are disposed in the pixel region 101 as viewed in the Z direction. Each mark portion 105 is disposed in the vicinity of corresponding one of four corner portions of the pixel region 101 as viewed in the Z direction.

FIG. 11B is a plan view of the detection unit 300 according to the eighth embodiment. The detection unit 300 includes the radiation detector 1 and the shielding member 200. The shielding member 200 is formed from a metal member capable of shielding a radiation. The shielding member 200 is disposed on the radiation incident side of the radiation detector 1. The shielding member 200 is disposed at a position overlapping with the entirety of the peripheral circuit region 103, that is, the entirety of the peripheral circuit portion 3 illustrated in FIG. 1 as viewed in the Z direction such that no radiation is radiated onto the peripheral circuit region 103.

The opening 201 that is a through hole is provided in the shielding member 200. The opening 201 is formed at a position corresponding to the pixel array 2 such that the radiation is incident on the pixel array 2. The opening 201 has a rectangular shape having an area approximately equal to the area of the pixel region 101 as viewed in the Z direction. That is, the pixel array 2 disposed in the pixel region 101 does not overlap with the shielding member 200 as viewed in the Z direction. The pixel array 2 (FIG. 1) disposed in the pixel region 101 is irradiated with a radiation having passed through the opening 201 of the shielding member 200. The mark portion 105 is used for aligning the shielding member 200 with the radiation detector 1 such that the shielding member 200 does not overlap with the pixel array 2.

In the configuration described above, the mark portion 105 of the eighth embodiment is connected to a predetermined potential, for example, the ground potential or the power source potential similarly to the first to seventh embodiments described above. As a result of this, the charge-up of the mark portion 105 is reduced, and operation failure and malfunction of the radiation detector 1 is suppressed. As described above, according to the eighth embodiment, a technique advantageous for stable operation of the radiation detector 1 is provided.

### Ninth Embodiment

A radiation detector according to a ninth embodiment will be described with reference to drawings. In the ninth embodiment, description of matter common to any of the first to eighth embodiments will be simplified or omitted, and difference from the first to eighth embodiments will be mainly described. The schematic configuration of the radiation detector 1 of the ninth embodiment is as described in the first embodiment with reference to FIG. 1. In addition, the schematic configuration of the detection unit 300 including the radiation detector 1 and the shielding member 200 of the ninth embodiment is as described in the first embodiment with reference to FIG. 2B.

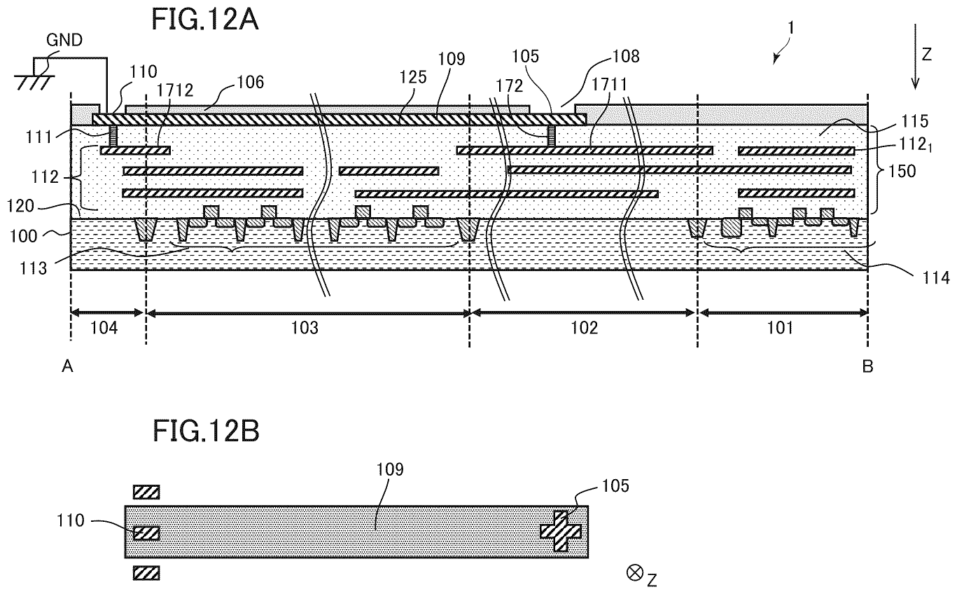

FIG. 12A is a section view of the radiation detector 1 according to the ninth embodiment. FIG. 12A illustrates a cross-section of the radiation detector 1 taken along the line A-B of FIG. 2A. FIG. 12B is a plan view for describing the connection state between a mark portion 105 and a pad electrode 110 according to the ninth embodiment.

The mark portion 105 is a conductor disposed in the outermost wiring layer. In the ninth embodiment, each mark portion 105 is connected to a pad electrode 110 through the wiring pattern 109 that is a solid wiring pattern. The mark portion 105 is visually recognized through the opening 108 of the passivation layer 106.

According to the configuration described above, the charges in the charged mark portion 105 can be discharged to the ground potential GND through the shortest path. In addition, since the wiring pattern 109 that is a solid wiring pattern also has a function of shielding light incident on the peripheral circuit region 103, erroneous operation of the transistor 113 of the peripheral circuit region 103 can be suppressed.

To be noted, the wiring layer 112₁ includes a wiring pattern 171₁ connected to the mark portion 105 through a via 172, and a wiring pattern 171₂ connected to the pad electrode 110 through a via 111. In the wiring layer 112₁, the wiring pattern 171₁ and the wiring pattern 171₂ are not connected.

### Tenth Embodiment

A radiation detector according to a tenth embodiment will be described with reference to drawings. In the tenth embodiment, description of matter common to any of the first to ninth embodiments will be simplified or omitted, and difference from the first to ninth embodiments will be mainly described. The schematic configuration of the radiation detector 1 of the tenth embodiment is as described in the first embodiment with reference to FIG. 1. In addition, the schematic configuration of the detection unit 300 including the radiation detector 1 and the shielding member 200 of the tenth embodiment is as described in the first embodiment with reference to FIG. 2B.

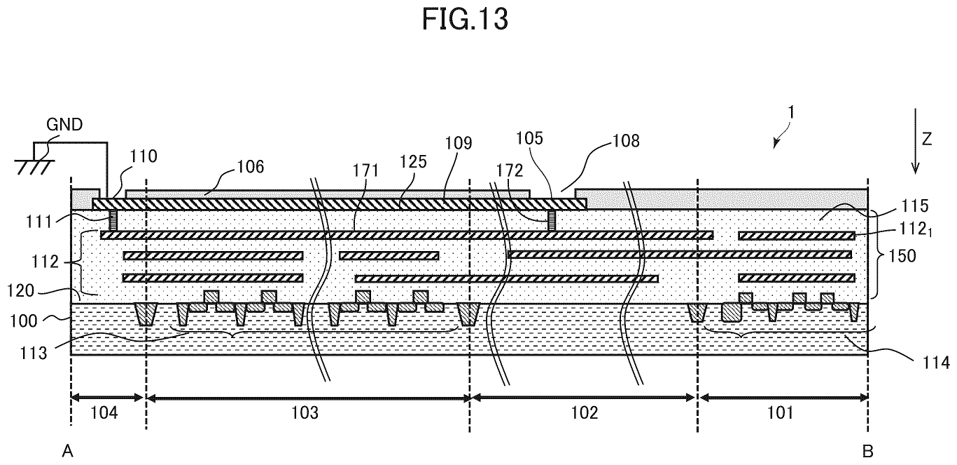

FIG. 13 is a section view of the radiation detector 1 according to the tenth embodiment. FIG. 13 illustrates a cross-section of the radiation detector 1 taken along the line A-B of FIG. 2A. In the tenth embodiment, the via 111 connected to the pad electrode 110 and the via 172 to which the mark portion 105 is connected are interconnected by the wiring pattern 171 of the wiring layer 112₁.

According to the configuration described above, the mark portion 105 and the pad electrode 110 are interconnected by the wiring pattern 109 and the wiring pattern 171, and therefore the electric resistance of the path for discharging the charges in the charged mark portion 105 to the ground potential GND is lower than in the ninth embodiment. Therefore, more charges can be discharged to the ground potential GND.

### Eleventh Embodiment

A radiation detector according to an eleventh embodiment will be described with reference to drawings. In the eleventh embodiment, description of matter common to any of the first to tenth embodiments will be simplified or omitted, and difference from the first to tenth embodiments will be mainly described. The schematic configuration of the radiation detector 1 of the eleventh embodiment is as described in the first embodiment with reference to FIG. 1. In addition, the schematic configuration of the detection unit 300 including the radiation detector 1 and the shielding member 200 of the eleventh embodiment is as described in the first embodiment with reference to FIG. 2B.

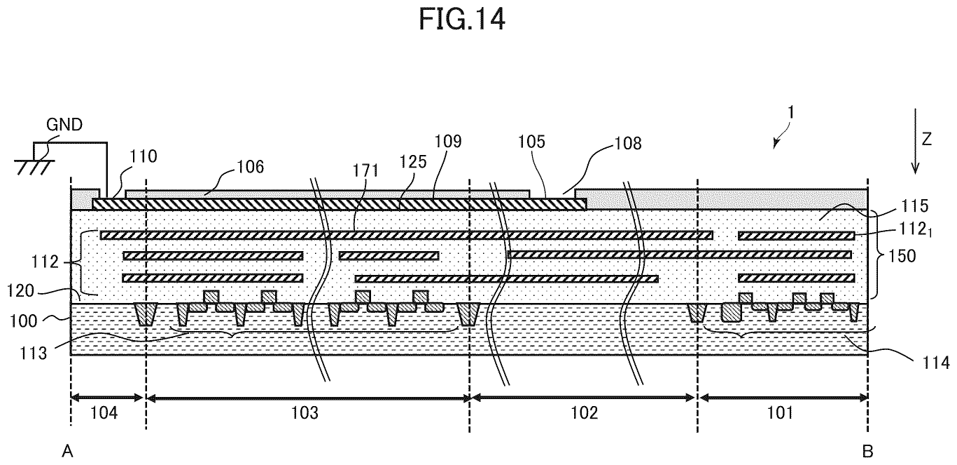

FIG. 14 is a section view of the radiation detector 1 according to the eleventh embodiment. FIG. 14 illustrates a cross-section of the radiation detector 1 taken along the line A-B of FIG. 2A. In the eleventh embodiment, the vias 111 and 172 are omitted from the radiation detector 1 of the tenth embodiment. As a result of this, the degree of freedom of the layout of the wiring layers 112 is improved.

### Twelfth Embodiment

A radiation detector according to a twelfth embodiment will be described with reference to drawings. In the twelfth embodiment, description of matter common to any of the first to eleventh embodiments will be simplified or omitted, and difference from the first to eleventh embodiments will be mainly described. The schematic configuration of the radiation detector 1 of the twelfth embodiment is as described in the first embodiment with reference to FIG. 1. In addition, the schematic configuration of the detection unit 300 including the radiation detector 1 and the shielding member 200 of the twelfth embodiment is as described in the first embodiment with reference to FIG. 2B.

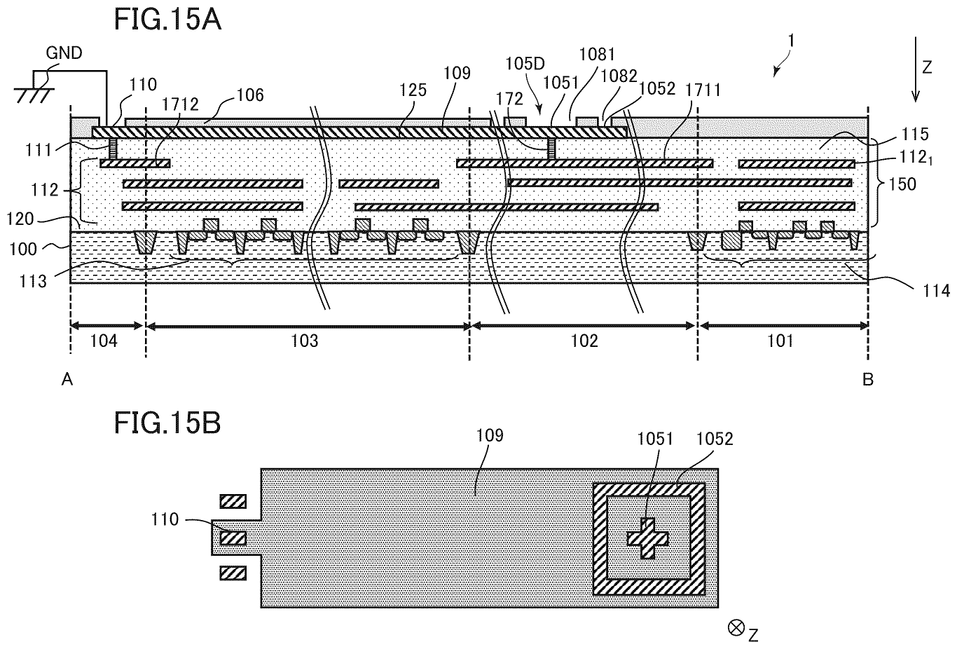

FIG. 15A is a section view of the radiation detector 1 according to the twelfth embodiment. FIG. 15A illustrates a cross-section of the radiation detector 1 taken along the line A-B of FIG. 2A. FIG. 15B is a plan view for describing the connection state between a mark portion 105D and a pad electrode 110 according to the twelfth embodiment.

The radiation detector 1 of the twelfth embodiment includes a mark portion 105D instead of the mark portion 105 illustrated in FIG. 12A. The mark portion 105D includes a mark 1051 having a plus shape in plan view, that is, as viewed in the Z direction, and a mark 1052 surrounding the mark 1051 having a plus shape. As viewed in the Z direction, the mark 1051 is disposed inside the mark 1052.

Specifically, the passivation layer 106 has an opening 1081 having a plus shape as viewed in the Z direction, and an opening 1082 having a quadrangular frame shape surrounding the opening 1081 as viewed in the Z direction. The openings 1081 and 1082 are through holes penetrating the passivation layer 106. The mark 1051 is constituted by a conductor disposed at a position corresponding to the opening 1081, and the mark 1052 is constituted by a conductor disposed at a position corresponding to the opening 1082. The marks 1051 and 1052 are disposed in the outermost wiring layer, and are connected to the wiring pattern 109. The marks 1051 and 1052 are respectively visually recognized through the openings 1081 and 1082. To be noted, the wiring pattern 109 is connected to the pad electrode 110 similarly to the ninth embodiment.

According to the configuration described above, the visibility of the mark portion 105D is improved. For example, when aligning the shielding member 200 (FIG. 2B) with the radiation detector 1, the mark 1052 having a frame shape is measured at a low magnification ratio, and thus the shielding member 200 is aligned with the radiation detector 1 with low precision. Then, the mark 1051 having a plus shape is measured at a high magnification ratio, and thus the shielding member 200 is aligned with the radiation detector 1 with high precision. Then, the shielding member 200 is fixed to a module including the radiation detector 1, and thus the detection unit 300 (FIG. 2B) is manufactured.

### Thirteenth Embodiment

Configuration examples of the detection unit 300 including the radiation detector 1 and the shielding member 200 have been described in the first to twelfth embodiments described above. In the thirteenth embodiment, a radiation imaging system including the detection unit 300 will be described.

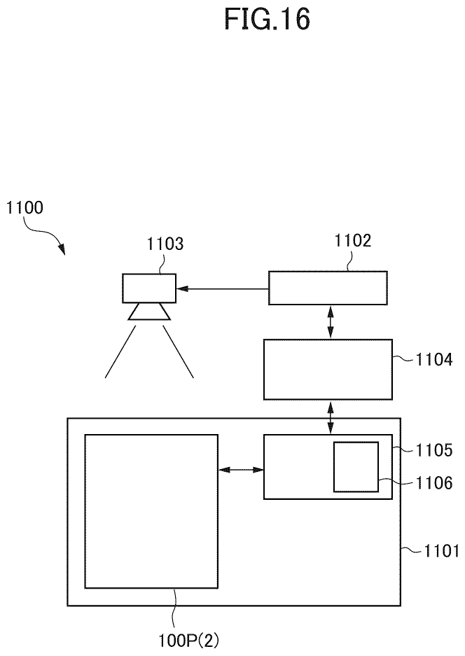

A radiation imaging system 1100 illustrated in FIG. 16 is a detection system including an imaging portion 1101 that is the detection unit 300 including the radiation detector 1 and the shielding member 200, an irradiation controller 1102, a radiation source 1103 serving as an energy beam radiating portion, and a computer 1104. The imaging portion 1101 includes an imaging panel 100P including the pixel array 2. The detection unit 300 including the radiation detector 1 described in any of the first to twelfth embodiments can be used as the imaging portion 1101.

The radiation source 1103 starts emission of the radiation in accordance with an irradiation command from the irradiation controller 1102. The radiation emitted from the radiation source 1103 passes through an imaging target (subject) and is incident on the imaging panel 100P of the imaging portion 1101. The radiation source 1103 stops the emission of the radiation in accordance with a stop command from the irradiation controller 1102.

The imaging portion 1101 is, for example, a flat panel detector used for radiographing for medical image diagnosis or non-destructive inspection. The imaging panel 100P of the imaging portion 1101 may be formed in a plate shape having a size corresponding to the imaging target. For example, in the imaging panel 100P, 3300×2800 pixels are disposed on a 550 mm×445 mm substrate.

The imaging portion 1101 may have a configuration of a direct conversion type that converts the radiation into a signal charge by detection diodes provided in the pixel array 2 of the imaging panel 100P. In addition, the imaging portion 1101 may have a configuration of an indirect conversion type that coverts the radiation into fluorescent light by a scintillator layer provided in an upper layer of the pixel array 2 of the imaging panel 100P and converts the fluorescent light into a signal charge by the detection diodes of the pixel array 2.

The imaging portion 1101 includes the imaging panel 100P described above, a controller 1105 for controlling the imaging panel 100P, and a signal processing portion 1106 for processing a signal output from the imaging panel 100P. The signal processing portion 1106 may, for example, perform A/D conversion on the signal output from the imaging panel 100P, and output the converted signal to the computer 1104 as digital image data. In addition, the signal processing portion 1106 may, for example, generate a stop signal for stopping the emission of the radiation from the radiation source 1103 on the basis of the signal output from the imaging panel 100P. The stop signal is supplied to the irradiation controller 1102 via the computer 1104, and the irradiation controller 1102 transmits a stop command to the radiation source 1103 in response to the stop signal.

The controller 1105 can be constituted by, for example, a programmable logic device (PLD) such as a field programmable gate array (FPGA), an application specific integrated circuit (ASIC), a general-purpose computer including a program, or a combination of part or all of these.

Although the signal processing portion 1106 is described as provided in the controller 1105 or as part of functions of the controller 1105 in the thirteenth embodiment, the configuration is not limited to this. The controller 1105 and the signal processing portion 1106 may be provided separately. Further, the signal processing portion 1106 may be provided separately from the imaging portion 1101. For example, the computer 1104 may have the function of the signal processing portion 1106. Therefore, the signal processing portion 1106 can be included in the radiation imaging system 1100 as a signal processing apparatus that processes the signal output from the imaging portion 1101.

The computer 1104 can perform control of the imaging portion 1101 and the irradiation controller 1102, and processing for receiving the radiation image data from the imaging portion 1101 and displaying the radiation image data as a radiation image. In addition, the computer 1104 can function as an input portion for inputting a condition for the user to capture a radiation image.

For example, the irradiation controller 1102 includes an irradiation switch, and when the irradiation switch is turned on by the user, transmits an irradiation command to the radiation source 1103, and transmits a start notification indicating the start of radiation of the radiation to the computer 1104. The computer 1104 having received the start notification notifies the controller 1105 of the imaging portion 1101 about the start of radiation of the radiation in response to the start notification. In accordance with this, the controller 1105 generates a signal corresponding to the incident radiation in the imaging panel 100P.

### Fourteenth Embodiment

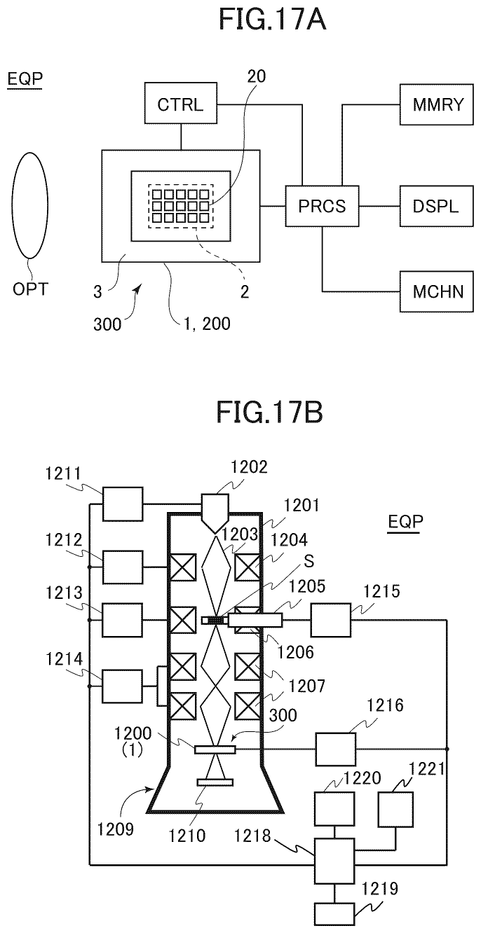

In the fourteenth embodiment, another example of a radiation imaging system will be described. FIG. 17A illustrates equipment EQP serving as a radiation imaging system. The equipment EQP includes the detection unit 300 including the radiation detector 1 and the shielding member 200.

The radiation detector 1 includes the pixel array 2 in which the pixels 20 are arranged in a matrix shape, and the peripheral circuit portion 3 disposed therearound. The peripheral circuit portion 3 includes a plurality of peripheral circuits. Further, the shielding member 200 is disposed on the radiation incident side of the radiation detector 1.

The equipment EQP can further include at least one of an optical system OPT, a control apparatus CTRL, a processing apparatus PRCS, a display apparatus DSPL, a storage apparatus MMRY, and a machine apparatus MCHN. The optical system OPT focuses the radiation on the radiation detector 1, and examples thereof include lenses, shutters, and mirrors. The optical system OPT may focus a corpuscular ray such as an electron beam or a proton beam on the radiation detector 1 depending on the kind or radiation that is used. The control apparatus CTRL controls the radiation detector 1, and is, for example, an ASIC. The processing apparatus PRCS processes the signal output from the radiation detector 1, and is an apparatus such as a CPU or an ASIC for constituting an analog front end (AFE) or a digital front end (DFE). The display apparatus DSPL is an apparatus such as an EL display apparatus or a liquid crystal display apparatus that displays the information obtained by the radiation detector 1 in the form of a visible image or the like. The storage apparatus MMRY is a magnetic device, a semiconductor device, or the like that stores information obtained by the radiation detector 1. The storage apparatus MMRY is a volatile memory such as a static random access memory (SRAM) or a dynamic random access memory (DRAM), or a nonvolatile memory such as a flash memory or a hard disk drive. The machine apparatus MCHN includes a movable portion or a propelling portion such as a motor or an engine.

The equipment EQP displays a signal output from the radiation detector 1 on the display apparatus DSPL, transmits the signal to the outside through a communication apparatus (not illustrated) included in the equipment EQP, and the like. Therefore, the equipment EQP preferably further includes the storage apparatus MMRY and the processing apparatus PRCS in addition to the storage circuit and the arithmetic operation circuit included in the radiation detector 1. The machine apparatus MCHN may be controlled on the basis of the signal output from the radiation detector 1.

The equipment EQP illustrated in FIG. 17A may be medical equipment such as an endoscope or radiation diagnosis equipment, measurement equipment such as a distance measurement sensor, or analysis equipment such as an electron microscope.

FIG. 17B is a schematic diagram illustrating a configuration of a transmission electron microscope (TEM) as an example of the equipment EQP. The equipment EQP as the electron microscope includes an electron beam source 1202 (electron gun) serving as an energy beam (electron beam) irradiation portion, an irradiation lens 1204, a vacuum chamber 1201 (lens barrel), an objective lens 1206, and a magnification lens system 1207. In addition, the equipment EQP includes a camera 1209 serving as an imaging portion. The camera 1209 includes the detection unit 300 including a direct radiation detector 1200 (direct electron detector) as the radiation detector 1 of a direct detection type. That is, the direct radiation detector 1200 corresponds to the radiation detector 1.

An electron beam 1203 that is an energy beam radiated from the electron beam source 1202 is focused by the irradiation lens 1204, and is radiated onto a sample S serving as an analysis target held by a sample holder. A space that the electron beam 1203 passes through is formed in the vacuum chamber 1201 (lens barrel), and this space is maintained under vacuum. The radiation detector 1 is disposed to face the vacuum space that the electron beam 1203 passes through. The electron beam 1203 having passed through the sample S is expanded by the objective lens 1206 and the magnification lens system 1207, and is projected onto the radiation detector 1. An electronic optical system for irradiating the sample S with an electron beam will be referred to as an irradiation optical system, and an electronic optical system for focusing the electron beam having passed through the sample S on the radiation detector 1 will be referred to as a focusing optical system.

The electron beam source 1202 is controlled by an electron beam source control apparatus 1211. The irradiation lens 1204 is controlled by an irradiation lens control apparatus 1212. The objective lens 1206 is controlled by an objective lens control apparatus 1213. The magnification lens system 1207 is controlled by a magnification lens system control apparatus 1214. A control mechanism 1205 of the sample holder is controlled by a holder control apparatus 1215 that controls the driving mechanism of the sample holder.

The electron beam 1203 having passed through the sample S is detected by the direct radiation detector 1200 of the camera 1209. The output signal from the direct radiation detector 1200 is processed by a signal processing apparatus 1216 and an image processing apparatus 1218 each serving as the processing apparatus PRCS, and thus an image signal is generated. The generated image signal (transmission electron image) is displayed on an image display monitor 1220 and an analysis monitor 1221 each corresponding to the display apparatus DSPL.

The camera 1209 is provided at a lower portion of the equipment EQP. At least part of the camera 1209 is provided in the vacuum chamber 1201 such that the part is exposed to the vacuum space formed in the vacuum chamber 1201.

The electron beam source control apparatus 1211, the irradiation lens control apparatus 1212, the objective lens control apparatus 1213, the magnification lens system control apparatus 1214, and the holder control apparatus 1215 are each connected to the image processing apparatus 1218. As a result of this, data can be mutually communicated therebetween to set the imaging conditions of the electron microscope. For example, the irradiation rate of the electron beam can be set to 0.5 electron/pix/frm or less. In this case, the electron beam source control apparatus 1211 and the image processing apparatus 1218 function as control means for controlling the irradiation rate of the radiation. The drive control of the sample holder, setting of the observation conditions of each lens, and the like can be performed in accordance with a signal from the image processing apparatus 1218.

The operator prepares the sample S serving as an imaging target, and sets the imaging conditions by using an input apparatus 1219 connected to the image processing apparatus 1218. Predetermined data is respectively input to the electron beam source control apparatus 1211, the irradiation lens control apparatus 1212, the objective lens control apparatus 1213, and the magnification lens system control apparatus 1214 such that desired acceleration voltage, magnification, and observation mode can be obtained. In addition, the operator inputs conditions such as the number of continuous view images, imaging start position, and movement speed of the sample holder to the image processing apparatus 1218 by using the input apparatus 1219 such as a mouse, a keyboard, or a touch panel. The image processing apparatus 1218 may be configured to automatically set the conditions regardless of the input from the operator.

The systems described in the thirteenth embodiment and the fourteenth embodiment described above are merely examples, and the radiation detectors described in the first to twelfth embodiments may be applied to a different system.

According to the present disclosure, a technique advantageous for stable operation of a radiation detector can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-190404, filed Nov. 7, 2023, and Japanese Patent Application No. 2024-108504, filed Jul. 4, 2024, which are hereby incorporated by reference herein in their entirety.

What is claimed is:

1. A radiation detector comprising:
a semiconductor substrate including a pixel portion and a peripheral circuit portion; and
a mark portion having conductivity,
wherein, in plan view, the mark portion is disposed in a first region or a third region among the first region, a second region, and the third region, the first region including the pixel portion, the second region including the peripheral circuit portion and being positioned outside the first region, the third region being positioned between the first region and the second region, and
wherein the mark portion is connected to a predetermined potential.

2. The radiation detector according to claim 1, wherein the mark portion is connected to the predetermined potential at least through wiring.

3. The radiation detector according to claim 2, wherein the wiring includes a second wiring pattern and a via, the second wiring pattern being adjacent to a first wiring pattern with an insulator therebetween and positioned between the first wiring pattern and the semiconductor substrate, the via interconnecting the mark portion and the second wiring pattern, the mark portion being disposed on the first wiring pattern.

4. The radiation detector according to claim 3, wherein the second wiring pattern overlaps with the mark portion in the plan view.

5. The radiation detector according to claim 4, wherein the second wiring pattern is formed in a size to be hidden under the mark portion in the plan view.

6. The radiation detector according to claim 3, wherein the via overlaps with the mark portion in the plan view.

7. The radiation detector according to claim 6, wherein the via is formed in a size to be hidden under the mark portion in the plan view.

8. The radiation detector according to claim 1, wherein the mark portion is connected to the predetermined potential at least via a well included in the semiconductor substrate.

9. The radiation detector according to claim 1, wherein the predetermined potential is a potential set by a power source.

10. The radiation detector according to claim 9, wherein the predetermined potential is a power source potential of the power source or a ground potential.

11. The radiation detector according to claim 9, wherein the power source is a constant voltage source.

12. The radiation detector according to claim 9, wherein the power source is a variable voltage source capable of adjusting the predetermined potential.

13. The radiation detector according to claim 1, wherein the radiation detector includes two or more mark portions each serving as the mark portion.

14. The radiation detector according to claim 13, wherein the two or more mark portions are respectively connected to two or more predetermined potentials different from each other and each serving as the predetermined potential.

15. The radiation detector according to claim 1, wherein the mark portion includes a frame-shaped mark disposed to surround the pixel portion in the plan view.

16. The radiation detector according to claim 15,
wherein the frame-shaped mark is connected to the predetermined potential at least through wiring, and
wherein the wiring includes a plurality of wiring patterns disposed to surround the pixel portion and interconnected by vias in the plan view.

17. The radiation detector according to claim 15, wherein the mark portion further includes a plus-shaped mark disposed on an inner side of the frame-shaped mark in the plan view.

18. A detection unit comprising:
the radiation detector according to claim 1; and
a shielding member disposed on a radiation incident side of the radiation detector and having an opening provided at a position corresponding to the pixel portion,
wherein the shielding member overlaps with entirety of the second region in the plan view.

19. A radiation imaging system comprising:
a radiation source configured to irradiate an imaging target with a radiation; and
the detection unit according to claim 18.
